(19) United States
(12) Patent Application Publication
(10) Pub. No.: US 2024/0213774 A1
(43) Pub. Date: Jun. 27, 2024

(54) POWER SUPPLY CONTROL DEVICE AND METHOD FOR CONTROLLING POWER SUPPLY CONTROL DEVICE

(71) Applicant: DENSO TEN Limited, Kobe (JP)

(72) Inventors: Daiki HAKUSHIMA, Kobe (JP); Takeshi Matsumoto, Kobe (JP); Minoru Yoshimura, Kobe (JP)

(73) Assignee: DENSO TEN Limited, Kobe (JP)

(21) Appl. No.: 18/394,353

(22) Filed: Dec. 22, 2023

(30) Foreign Application Priority Data
Dec. 27, 2022 (JP) 2022-210893

(51) Int. Cl. H02J 3/00; G01R 31/40

(52) U.S. Cl. CPC H02J 3/0073; G01R 31/40; H02J 3/001

(57) ABSTRACT

A power supply control device includes: an inter-system connection unit configured to disconnect electrical connection between a first system and a second system, a first detection device configured to detect an abnormality of the first system or the second system when a state in which a physical quantity indicating a state of the first system or a state of the second system exceeds a first threshold for abnormality determination from a normal value side continues for a first detection time, and block the inter-system connection unit, and a second detection device configured to specify in the first system and the second system, as an abnormal system, a system in which a state in which the physical quantity exceeds a second threshold for abnormality determination from the normal value side continues for a second detection time shorter than the first detection time, after the first detection device detects an abnormality.

### CROSS-REFERENCE TO RELATED APPLICATIONS

This application is based on and claims priority under 35 USC 119 from Japanese Patent Application No.2022-210893 filed on Dec. 27, 2022, the entire content of which is incorporated herein by reference.

### TECHNICAL FIELD

The present invention relates to a power supply control device and a method for controlling a power supply control device.

### BACKGROUND ART

There is a power supply control device including a first system that supplies electric power of a first power supply to a first load, a second system that supplies electric power of a second power supply to a second load, and an inter-system connection unit capable of disconnecting electrical connection between the first system and the second system.

When a voltage of the first system or the second system drops continuously for a first predetermined time, the power supply control device primarily determines the occurrence of power supply failure, and disconnects the electrical connection between the first system and the second system by the inter-system connection unit. After the electrical connection between the first system and the second system is disconnected by the inter-system connection unit, the power supply control device further performs a secondary determination to confirm the occurrence of the power supply failure when the voltage drops continuously for a second predetermined time. When electric power is supplied to a load from a system in which no power supply failure occurs, a fail safe control is executed by the load connected to the system in which no power supply failure occurs (for example, refer to JP2022-125004A).

In the above-described power supply control device, the first predetermined time is set to be shorter than the second predetermined time.

The power supply control device disconnects the electrical connection between the first system and the second system by the inter-system connection unit when the voltage drops continuously for the first predetermined time and, for example, there is a tendency of a ground fault due to power supply failure in the first system or the second system. Accordingly, the power supply control device prevents the influence of the ground fault on a normal system.

However, the power supply control device in the related art may erroneously detect the occurrence of the ground fault in the primary determination when the voltage drops due to, for example, a voltage fluctuation in a state in which no ground fault actually occurs. Therefore, when no ground fault actually occurs, a function of the load may be limited until the system is determined to be normal in the secondary determination and returns to an original normal state. In addition, the function of the load is limited when a power storage amount of a power supply to be used as a backup power supply in the first power supply and the second power supply decreases in the secondary determination. For example, when the power storage amount of the backup power supply decreases, a part of the function of the load that can be executed normally is prohibited.

### SUMMARY OF INVENTION

The present invention has been made in view of the above, and an object thereof is to prevent a function of a load from being limited by reducing erroneous detection of power supply failure.

A power supply control device according to an aspect of an embodiment includes an inter-system connection unit, a first detection device, and a second detection device. The inter-system connection unit can disconnect electrical connection between a first system that supplies electric power of a first power supply to a first load and a second system that supplies electric power of a second power supply to a second load. When a state in which a physical quantity indicating a state of the first system or a state of the second system exceeds a first threshold for abnormality determination from a normal value side continues for a first detection time, the first detection device detects an abnormality of the first system or an abnormality of the second system, and blocks the inter-system connection unit. The second detection device specifies in the first system and the second system, as an abnormal system, a system in which a state in which the physical quantity exceeds a second threshold for abnormality determination from the normal value side continues for a second detection time shorter than the first detection time, after the first detection device detects an abnormality.

According to the aspect of the embodiment, it is possible to prevent a function of a load from being limited by reducing erroneous detection of power supply failure.

### BRIEF DESCRIPTION OF DRAWINGS

FIG. 1 is a diagram illustrating a configuration example of a power supply control device 1 according to a first embodiment;

FIG. 2 is a diagram illustrating a normal state in which no ground fault occurs in a first system and a second system;

FIG. 3 is a diagram illustrating a state in which a power storage amount of a second power supply is smaller than a first predetermined power storage amount;

FIG. 4 is a diagram illustrating a state in which a ground fault occurs in the first system;

FIG. 5 is a diagram illustrating a state in which a ground fault occurs in the first system, an inter-system connection unit is turned off, and a battery switch is turned on;

FIG. 6 is a flowchart illustrating an abnormality occurrence processing according to the first embodiment;

FIG. 7 is a flowchart illustrating an abnormality occurrence processing according to the first embodiment;

FIG. 8 is a flowchart illustrating an abnormality occurrence processing according to the first embodiment;

FIG. 9 is a flowchart illustrating an abnormality occurrence processing according to a second embodiment; and

FIG. 10 is a diagram illustrating a second detection device according to a modification.

### DESCRIPTION OF EMBODIMENTS

Hereinafter, a power supply control device and a method for controlling a power supply control device according to embodiments will be described in detail with reference to the accompanying drawings. The present invention is not limited to the present embodiments. Hereinafter, a power supply control device that is mounted on a vehicle having an automatic driving function and supplies electric power to a load will be described as an example, but the power supply control device according to the embodiment may be mounted on a vehicle not having an automatic driving function.

Hereinafter, a case in which the vehicle on which the power supply control device is mounted is an electric automatic vehicle or a hybrid automatic vehicle will be described, and the vehicle on which the power supply control device is mounted may be an engine automatic vehicle that travels by using an internal combustion engine.

When an abnormality occurs in a power supply system of a first power supply, the power supply control device according to the embodiment may be mounted on any device that backs up the first power supply by a power supply system of a second power supply. The abnormality includes power supply failure. The power supply failure occurs due to, for example, a ground fault. Hereinafter, a case in which an abnormality is a ground fault will be described.

### First Embodiment

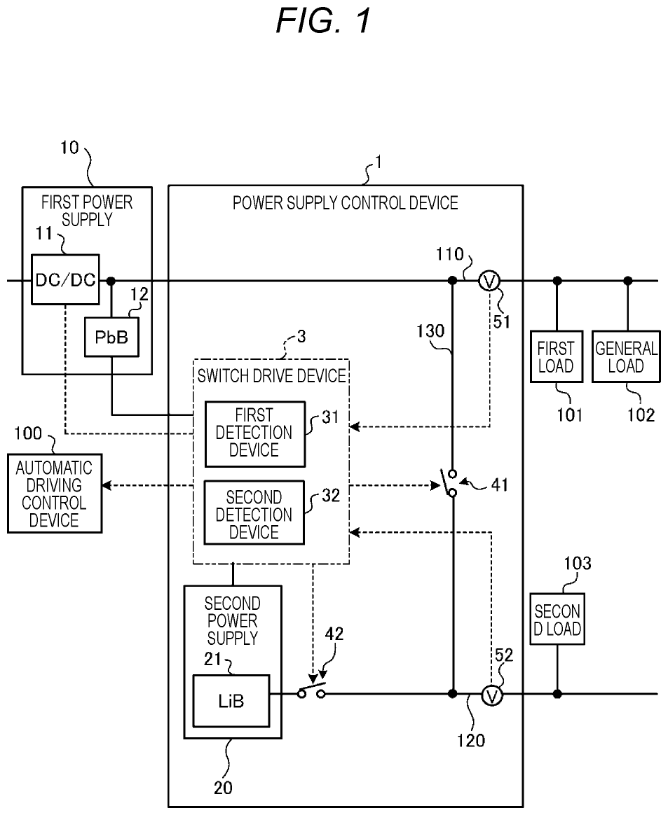

FIG. 1 is a diagram illustrating a configuration example of a power supply control device 1 according to a first embodiment. As illustrated in FIG. 1, the power supply control device 1 according to the embodiment is connected to a first power supply 10, a first load 101, a general load 102, a second load 103, and an automatic driving control device 100. The power supply control device 1 includes a first system 110 and a second system 120. The first system 110 supplies electric power of the first power supply 10 to the first load 101 and the general load 102. The second system 120 supplies electric power of a second power supply 20 to be described later to the second load 103.

The first load 101 includes a load for automatic driving. For example, the first load 101 includes a steering motor, an electric brake device, an in-vehicle camera, and the like that operate during automatic driving.

The general load 102 is a load that is not directly involved in automatic driving, and includes, for example, a display, an air conditioner, audio, video, and various lights.

The second load 103 includes a part of an automatic driving function provided in the first load 101. For example, the second load 103 includes a minimum limit device for a fail operation (FOP), such as a steering motor, an electric brake device, and a radar. The first load 101, the general load 102, and the second load 103 operate with electric power supplied from the power supply control device 1. The FOP is a control for evacuating the vehicle to a safe place by the automatic driving control device 100. Even when a ground fault occurs in one of the first system 110 and the second system 120 during automatic driving, the FOP is executed using another system.

The automatic driving control device 100 is a device for controlling automatic driving of a vehicle. The automatic driving control device 100 causes the vehicle to travel by automatic driving by operating the first load 101 and the second load 103. In addition, when a ground fault occurs in the first system 110 during automatic driving, the automatic driving control device 100 can execute the FOP using the second load 103. When a ground fault occurs in the second system 120 during automatic driving, the automatic driving control device 100 can execute the FOP using the first load 101.

The automatic driving control device 100 outputs a signal indicating that automatic driving is being performed to the power supply control device 1. For example, the automatic driving control device 100 outputs a signal indicating that automatic driving is being performed to a first detection device 31 of the power supply control device 1 to be described later. When automatic driving is not being performed, the automatic driving control device 100 does not output the signal indicating that automatic driving is being performed to the power supply control device 1. When automatic driving is not being performed, the automatic driving control device 100 may output a signal indicating that automatic driving is not being performed to the power supply control device 1.

The first power supply 10 includes a DC and DC converter (hereinafter, referred to as “DC and DC 11”) and a lead battery (hereinafter, referred to as “PbB 12”). A battery of the first power supply 10 may be any secondary battery other than the PbB 12.

The DC and DC 11 is connected to a generator (not shown) and a high-voltage battery (not shown) having a voltage larger than that of the PbB 12. The DC and DC 11 steps down a voltage of the generator and the voltage of the high-voltage battery and outputs the stepped-down voltages to the first system 110. The generator is, for example, an alternator that converts kinetic energy of the traveling vehicle into electricity to generate electric power. The high-voltage battery is, for example, a vehicle drive battery mounted on the electric automatic vehicle and the hybrid automatic vehicle.

When the first power supply 10 is mounted on the engine automatic vehicle, the alternator (generator) is provided instead of the DC and DC 11. The DC and DC 11 charges the PbB 12 and supplies electric power to the first load 101 and the general load 102. The DC and DC 11 supplies electric power to the second load 103 and charges the second power supply 20 to be described later.

The power supply control device 1 includes the second power supply 20, an inter-system connection unit 41, a battery switch 42, a switch drive device 3, a first voltage sensor 51, and a second voltage sensor 52. The second power supply 20 is a backup power supply when the first power supply 10 cannot supply electric power. The second power supply 20 includes a lithium ion battery (hereinafter, referred to as “LiB 21”). A battery of the second power supply 20 may be any secondary battery other than the LiB 21.

The inter-system connection unit 41 is provided in an inter-system line 130 that connects the first system 110 and the second system 120. The inter-system connection unit 41 can disconnect electrical connection between the first system 110 and the second system 120. The inter-system connection unit 41 is a switch capable of connecting and disconnecting the first system 110 and the second system 120. The inter-system connection unit 41 may be the DC and DC converter that conducts between the first system 110 and the second system 120 by being activated. When the inter-system connection unit 41 is the DC and DC converter, the first system 110 and the second system 120 are blocked by stopping an operation of the DC and DC converter.

Connecting the inter-system connection unit 41 means electrically connecting, that is, conducting the first system 110 and the second system 120 to each other. In addition, disconnecting the inter-system connection unit 41 means disconnecting, that is, blocking the electrical connection between the first system 110 and the second system 120.

The battery switch 42 is a switch that connects the second power supply 20 to the second system 120. The battery switch 42 is a switch capable of connecting and disconnecting the second power supply 20 and the second system 120.

The first voltage sensor 51 is provided in the first system 110. The first voltage sensor 51 detects a voltage of the first system 110. The first voltage sensor 51 outputs a detection result to the switch drive device 3. The second voltage sensor 52 is provided in the second system 120. The second voltage sensor 52 detects a voltage of the second system 120. The second voltage sensor 52 outputs a detection result to the switch drive device 3.

The switch drive device 3 includes a microcomputer including a central processing unit (CPU), a read only memory (ROM), a random access memory (RAM), and the like, and various circuits.

The switch drive device 3 may include hardware such as an application specific integrated circuit (ASIC) or a field programmable gate array (FPGA).

The switch drive device 3 controls an operation of the power supply control device 1. The switch drive device 3 includes the first detection device 31 and a second detection device 32. At least a part of functions of the first detection device 31 and the second detection device 32 may be integrated.

The first detection device 31 is the microcomputer. The first detection device 31 functions when the CPU executes a program stored in the ROM by using the RAM as a work area.

The first detection device 31 detects a ground fault in the first system 110 or a ground fault in the second system 120 based on a physical quantity indicating a state of the first system 110 or a state of the second system 120, a first detection time, and a first threshold. The physical quantity is a voltage or a current. Hereinafter, the case in which the physical quantity is the voltage will be described. The details of processing in the first detection device 31 will be described later.

The first detection time is a preset time. The first detection time is a time during which a voltage change in each of the systems 110 and 120 can be prevented from being erroneously detected as the occurrence of a ground fault in a state in which no ground fault occurs in any of the first system 110 and the second system 120. The first detection time is, for example, 100 ms.

The first threshold is a preset value. The first threshold is a threshold for abnormality determination. The first threshold is a threshold related to the physical quantity. The first threshold is set with respect to a normal value of the physical quantity. The normal value of the physical quantity is a value of a physical quantity in the state in which no ground fault occurs in any of the first system 110 and the second system 120. For example, the normal value of the physical quantity is an average value of physical quantities in the state in which no ground fault occurs in any of the first system 110 and the second system 120. The normal value of the physical quantity is set based on results of experiments, simulations, and the like. When the physical quantity is the voltage, the first threshold is a threshold related to the voltage. When the physical quantity is the voltage, the first threshold is smaller than the normal value of the physical quantity.

When a state in which a voltage detected by the second voltage sensor 52 (hereinafter, referred to as a “second system voltage V2”) exceeds the first threshold from a normal value side of the voltage continues for the first detection time or longer, the first detection device 31 detects the ground fault in the first system 110 or the ground fault in the second system 120. Specifically, when a state in which the second system voltage V2 is smaller than the first threshold continues for the first detection time or longer, the first detection device 31 detects the ground fault in the first system 110 or the ground fault in the second system 120. When the state in which the second system voltage V2 is smaller than the first threshold continues for the first detection time or longer, the first detection device 31 temporarily determines the occurrence of a ground fault.

The first detection device 31 may detect the ground fault in the first system 110 or the ground fault in the second system 120 based on a voltage detected by the first voltage sensor 51 (hereinafter, referred to as a “first system voltage V1”).

The first detection device 31 controls the inter-system connection unit 41 and the battery switch 42. The details of processing related to the inter-system connection unit 41 and the battery switch 42 will be described later.

The first detection device 31 can switch the inter-system connection unit 41 ON or OFF. The first system 110 and the second system 120 are electrically connected to each other by turning on the inter-system connection unit 41. The first system 110 and the second system 120 are electrically disconnected from each other by turning off the inter-system connection unit 41.

The first detection device 31 can switch the battery switch 42 ON or OFF. The second power supply 20 and the second system 120 are electrically connected to each other by turning on the battery switch 42. The second power supply 20 and the second system 120 are electrically disconnected from each other by turning off the battery switch 42.

The second detection device 32 is the microcomputer. The second detection device 32 functions when the CPU executes a program stored in the ROM by using the RAM as a work area. The second detection device 32 may be implemented by a hardware circuit.

The second detection device 32 specifies an abnormal system in which a ground fault occurs in the first system 110 and the second system 120 based on a physical quantity, a second detection time, and a second threshold. The second detection device 32 specifies an abnormal system after the ground fault in the first system 110 or the ground fault in the second system 120 is detected by the first detection device 31 and the electrical connection between the first system 110 and the second system 120 is disconnected by the inter-system connection unit 41. The details of processing in the second detection device 32 will be described later.

The second detection time is a preset time. The second detection time is shorter than the first detection time. The second detection time is a time for confirming the occurrence of a ground fault early by detecting a voltage drop after the ground fault is detected by the first detection device 31. The second detection time is, for example, 4 ms.

The second threshold is a preset value. The second threshold is a threshold for abnormality determination. The second threshold is a threshold related to the physical quantity. The second threshold is set with respect to a normal value of the physical quantity. When the physical quantity is a voltage, the second threshold is a threshold related to the voltage. When the physical quantity is the voltage, the second threshold is smaller than the normal value of the physical quantity. For example, the second threshold is the same value as the first threshold.

When a state in which the first system voltage V1 exceeds the second threshold from the normal value side of the voltage continues for the second detection time or longer, the second detection device 32 detects the ground fault in the first system 110. Specifically, when a state in which the first system voltage V1 is smaller than the second threshold continues for the second detection time or longer, the second detection device 32 detects the ground fault in the first system 110. The second detection device 32 specifies the first system 110 as an abnormal system in which a ground fault occurs. The second detection device 32 makes a final determination on the occurrence of the ground fault.

When the state in which the first system voltage V1 is smaller than the second threshold does not continue for the second detection time or longer, the second detection device 32 does not detect the ground fault in the first system 110. When the first system voltage V1 is equal to or larger than the second threshold, the second detection device 32 does not detect the ground fault in the first system 110. That is, the second detection device 32 determines that the first system 110 is normal. For example, when the first system voltage V1 is equal to or larger than the second threshold during the second detection time, the second detection device 32 determines that the first system 110 is normal.

When a state in which the second system voltage V2 exceeds the second threshold from the normal value side of the voltage continues for the second detection time or longer, the second detection device 32 detects the ground fault in the second system 120. Specifically, when a state in which the second system voltage V2 is smaller than the second threshold continues for the second detection time or longer, the second detection device 32 detects the ground fault in the second system 120. The second detection device 32 specifies the second system 120 as an abnormal system in which a ground fault occurs. The second detection device 32 makes a final determination on the occurrence of the ground fault.

When the state in which the second system voltage V2 is smaller than the second threshold does not continue for the second detection time or longer, the second detection device 32 does not detect the ground fault in the second system 120. When the second system voltage V2 is equal to or larger than the second threshold, the second detection device 32 does not detect the ground fault in the second system 120. That is, the second detection device 32 determines that the second system 120 is normal. For example, when the second system voltage V2 is equal to or larger than the second threshold during the second detection time, the second detection device 32 determines that the second system 120 is normal.

When it is determined that both the first system 110 and the second system 120 are normal, the second detection device 32 determines that the ground fault detection by the first detection device 31 is erroneous detection. The temporary determination by the first detection device 31 is cancelled. The temporary determination by the first detection device 31 is cancelled by the first detection device 31 based on a result of the erroneous detection determination by the second detection device 32.

The second detection device 32 controls the inter-system connection unit 41 and the battery switch 42. The details of processing related to the inter-system connection unit 41 and the battery switch 42 will be described later.

The second detection device 32 can switch the inter-system connection unit 41 ON or OFF. The second detection device 32 can switch the battery switch 42 ON or OFF.

When the power supply control device 1 is activated, the first detection device 31 turns on the inter-system connection unit 41 and turns off the battery switch 42. When no ground fault is detected in each of the systems 110 and 120, that is, when each of the systems 110 and 120 is normal, the first detection device 31 turns on the inter-system connection unit 41 and turns off the battery switch 42.

When each of the systems 110 and 120 is normal and a power storage amount of the second power supply 20 is smaller than a preset first predetermined power storage amount, the first detection device 31 turns on the battery switch 42. Accordingly, the second power supply 20 is charged by supplying electric power from the first power supply 10 to the second power supply 20. The first predetermined power storage amount is a power storage amount by which the FOP can be executed by supplying electric power from the second power supply 20 to the second load 103 when a ground fault occurs in the first system 110 during automatic driving.

When charging of the second power supply 20 is started and the power storage amount of the second power supply 20 is larger than a preset second predetermined power storage amount, the first detection device 31 turns off the battery switch 42. The second predetermined power storage amount is larger than the first predetermined power storage amount. The power storage amount is, for example, a state of charge (SOC). A charging rate, a remaining capacity, and the like may be used instead of the power storage amount.

At least a part of the control of the inter-system connection unit 41 and the battery switch 42 may be performed by the second detection device 32.

When the ground fault in the first system 110 or the ground fault in the second system 120 is detected, the first detection device 31 turns off the inter-system connection unit 41 and turns on the battery switch 42.

When the ground fault in the second system 120 is specified, the second detection device 32 turns off the battery switch 42 while keeping the inter-system connection unit 41 off.

When no ground fault in the first system 110 or the second system 120 is detected, the first detection device 31 outputs an automatic driving permission signal indicating that automatic driving is enabled to the automatic driving control device 100. Specifically, when no ground fault in the first system 110 or the second system 120 is detected and the power storage amount of the second power supply 20 is equal to or larger than the first predetermined power storage amount, the first detection device 31 outputs the automatic driving permission signal to the automatic driving control device 100.

Even when no ground fault in the first system 110 or the second system 120 is detected, in a case in which the power storage amount of the second power supply 20 is smaller than the first predetermined power storage amount, the first detection device 31 does not output the automatic driving permission signal to the automatic driving control device 100. In this case, the first detection device 31 outputs an automatic driving prohibition signal indicating that automatic driving is disabled to the automatic driving control device 100.

When a ground fault in the first system 110 or the second system 120 is detected, the first detection device 31 outputs an FOP temporary determination signal indicating that a ground fault in the first system 110 or the second system 120 is detected to the automatic driving control device 100. When the FOP temporary determination signal is output to the automatic driving control device 100, the automatic driving control device 100 operates the first load 101 with electric power supplied from the first power supply 10. When the FOP temporary determination signal is output to the automatic driving control device 100, the automatic driving control device 100 operates the second load 103 with electric power supplied from the second power supply 20.

When a ground fault in the first system 110 or the second system 120 is specified, the second detection device 32 outputs an FOP final determination signal indicating that a ground fault in the first system 110 or the second system 120 is specified to the automatic driving control device 100. When the FOP final determination signal is output to the automatic driving control device 100, the automatic driving control device 100 executes the FOP according to the system in which no ground fault is specified. That is, the second detection device 32 shifts to the FOP by outputting the FOP final determination signal to the automatic driving control device 100.

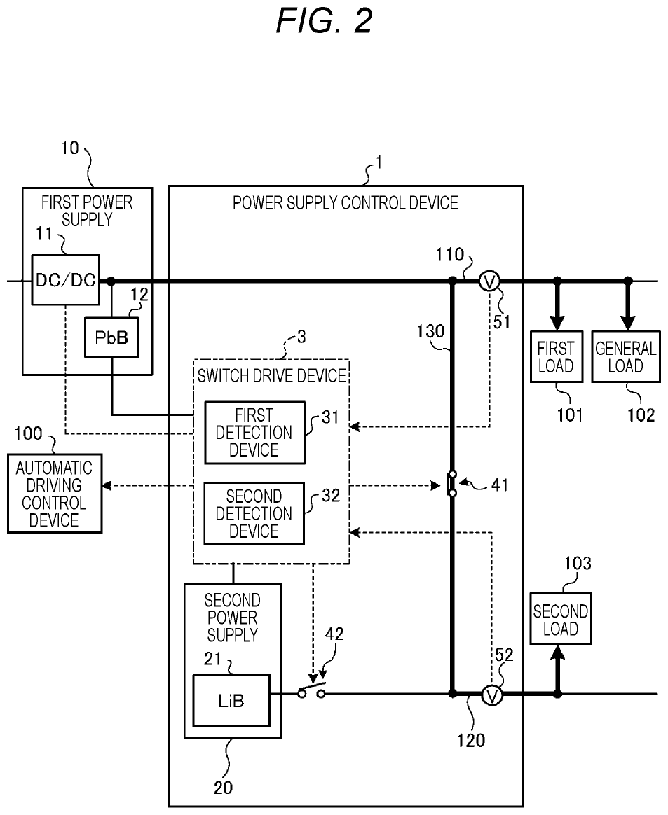

Next, an operation of the switch drive device 3 will be described with reference to FIGS. 2 to 5.

In a normal state in which no ground fault occurs in the first system 110 and the second system 120, as illustrated in FIG. 2, the first detection device 31 turns off the battery switch 42 and turns on the inter-system connection unit 41. FIG. 2 is a diagram illustrating the normal state in which no ground fault occurs in the first system 110 and the second system 120. FIG. 2 shows a state in which the power storage amount of the second power supply 20 is equal to or larger than the first predetermined power storage amount. In this case, electric power is supplied from the first power supply 10 to the first load 101, the general load 102, and the second load 103. The first detection device 31 outputs the automatic driving permission signal to the automatic driving control device 100.

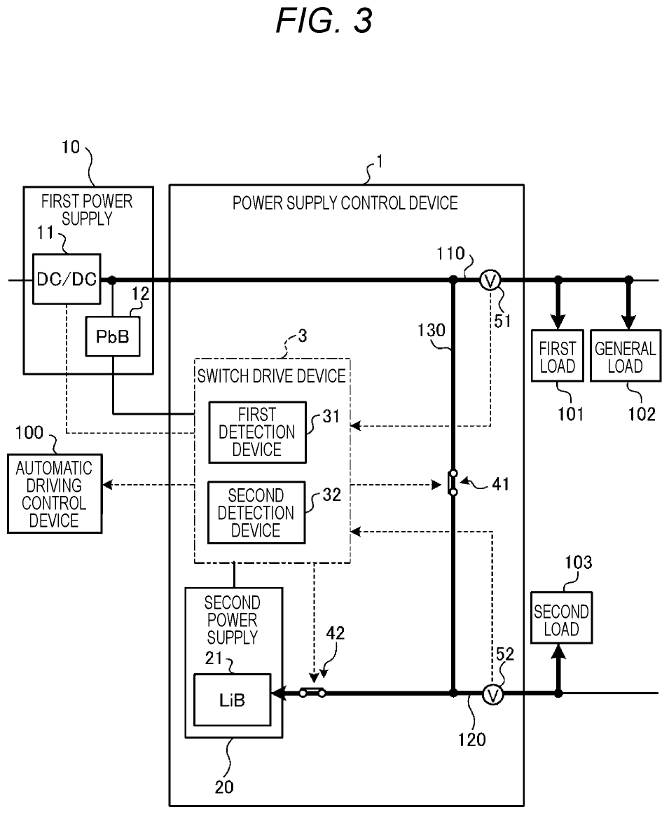

Even in the normal state in which no ground fault occurs in the first system 110 and the second system 120, when the power storage amount of the second power supply 20 is smaller than the first predetermined power storage amount, the first detection device 31 turns on the battery switch 42 as illustrated in FIG. 3. FIG. 3 is a diagram illustrating the state in which the power storage amount of the second power supply 20 is smaller than the first predetermined power storage amount. The inter-system connection unit 41 is turned on. Accordingly, the electric power is supplied from the first power supply 10 to the second power supply 20 to charge the second power supply 20. The first detection device 31 outputs the automatic driving prohibition signal to the automatic driving control device 100.

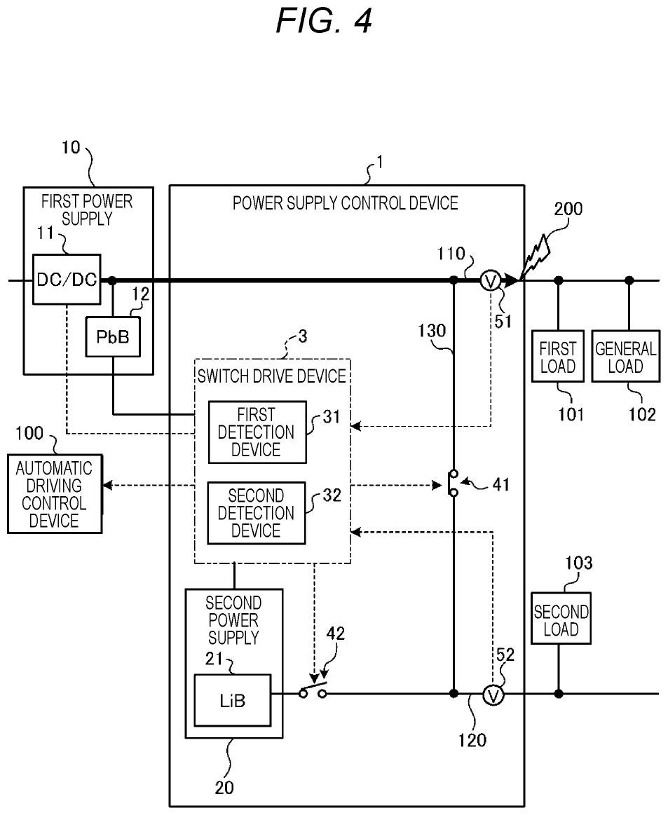

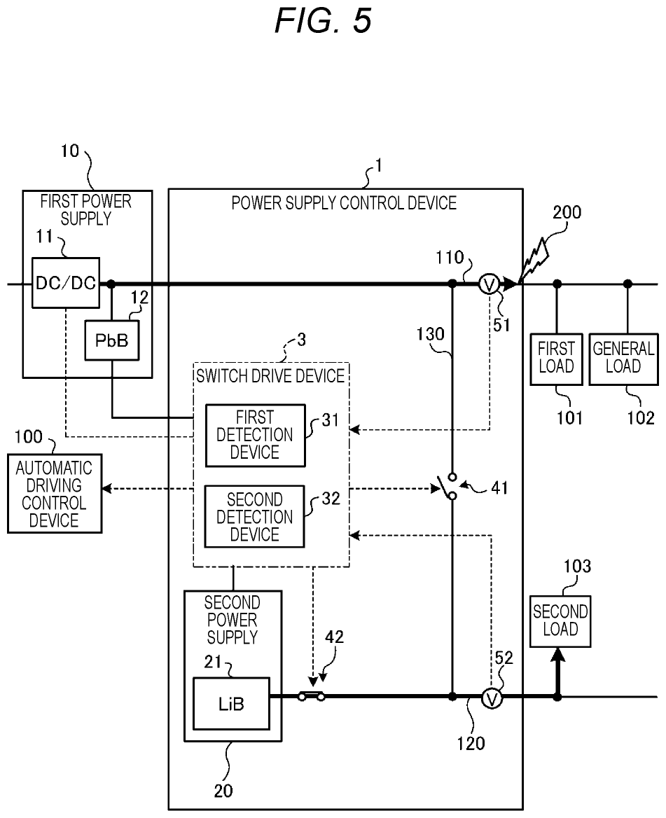

When a ground fault occurs in the first system 110 or the second system 120, for example, when a ground fault 200 occurs in the first system 110 as illustrated in FIG. 4, an overcurrent flows toward a ground fault point. Therefore, the voltages detected by the first voltage sensor 51 and the second voltage sensor 52 drop. FIG. 4 is a diagram illustrating a state in which the ground fault 200 occurs in the first system 110. When a state in which the voltage is smaller than the first threshold continues for the first detection time or longer, the first detection device 31 detects a ground fault in the first system 110 or the second system 120. When the ground fault 200 is detected, the first detection device 31 turns on the battery switch 42 and turns off the inter-system connection unit 41 as illustrated in FIG. 5. The first detection device 31 outputs the FOP temporary determination signal to the automatic driving control device 100. FIG. 5 is a diagram illustrating a state in which the ground fault 200 occurs in the first system 110, the inter-system connection unit 41 is turned off, and the battery switch 42 is turned on.

When a state in which the voltage of the first system 110 is smaller than the second threshold continues for the second detection time or longer after a ground fault is detected by the first detection device 31, the second detection device 32 detects the ground fault in the first system 110. That is, the second detection device 32 specifies the first system 110 as an abnormal system. When the second detection device 32 specifies the abnormal system, as illustrated in FIG. 5, the second detection device 32 turns on the battery switch 42 and keeps the inter-system connection unit 41 off. The second detection device 32 outputs the FOP final determination signal to the automatic driving control device 100. Accordingly, the automatic driving control device 100 executes the FOP by controlling the second load 103 based on the electric power of the second power supply 20.

When a state in which the voltage of the second system 120 is smaller than the second threshold continues for the second detection time or longer after a ground fault is detected by the first detection device 31, the second detection device 32 detects the ground fault in the second system 120. That is, the second detection device 32 specifies the second system 120 as an abnormal system.

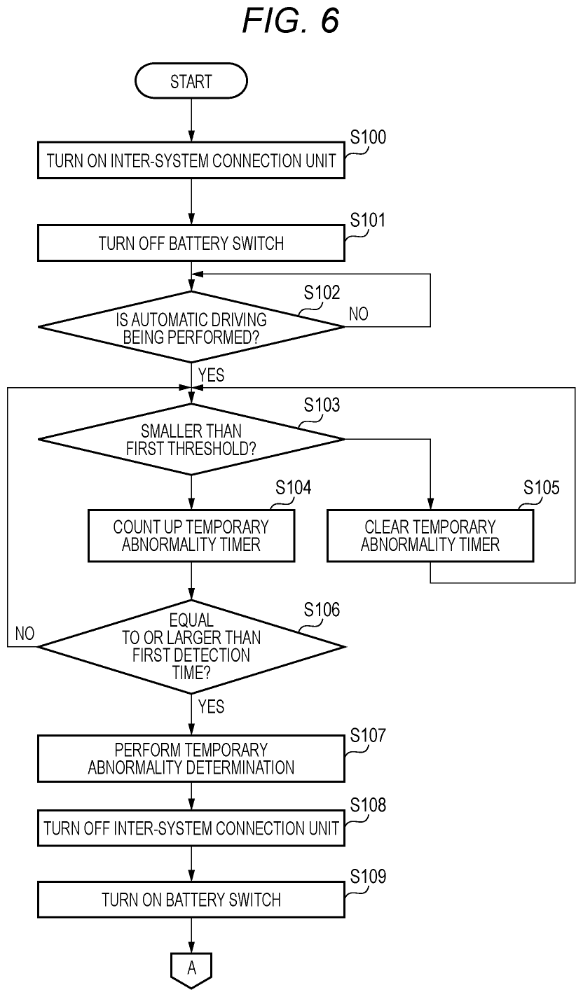

Next, an abnormality occurrence processing according to the first embodiment will be described with reference to FIGS. 6 to 8. FIGS. 6 to 8 are a flowchart illustrating the abnormality occurrence processing according to the first embodiment. In the abnormality occurrence processing, the first detection device 31 and the second detection device 32 are implemented by a single microcomputer.

When the power supply control device 1 is activated, the first detection device 31 turns on the inter-system connection unit 41 (S100). Next, the first detection device 31 turns off the battery switch 42 (S101). Accordingly, the electric power is supplied from the first power supply 10 to the first load 101, the general load 102, and the second load 103.

Next, the first detection device 31 determines whether automatic driving is being performed (S102). The first detection device 31 determines whether a signal indicating that automatic driving is being performed is acquired from the automatic driving control device 100. The first detection device 31 determines that automatic driving is being performed when the signal indicating that automatic driving is being performed is acquired. The first detection device 31 determines that automatic driving is not being performed when no signal indicating that automatic driving is being performed is acquired. The first detection device 31 determines that manual driving is being performed when no signal indicating that automatic driving is being performed is acquired.

When it is determined that automatic driving is not being performed (S102: No), the first detection device 31 repeatedly determines whether automatic driving is being performed (S102).

When it is determined that the automatic driving is being performed (S102: Yes), the first detection device 31 determines whether the second system voltage V2 is smaller than the first threshold (S103). That is, the first detection device 31 determines whether a voltage drop occurs in the first system 110 or the second system 120.

When it is determined that the second system voltage V2 is smaller than the first threshold (S103: Yes), the first detection device 31 counts up a temporary abnormality timer (S104). The first detection device 31 includes the temporary abnormality timer. A value of the temporary abnormality timer is set to “0” as an initial value. The value of the temporary abnormality timer indicates a duration time during which the second system voltage V2 is smaller than the first threshold. That is, the first detection device 31 measures the time during which the second system voltage V2 is continuously smaller than the first threshold using the temporary abnormality timer.

When it is determined that the second system voltage V2 is equal to or larger than the first threshold (S103: No), the first detection device 31 clears the temporary abnormality timer (S105). That is, when it is determined that the second system voltage V2 is equal to or larger than the first threshold, the first detection device 31 resets the value of the temporary abnormality timer to the initial value. After the temporary abnormality timer is cleared, the first detection device 31 returns to step S103 and repeats the above-described processing.

Next, the first detection device 31 determines whether the value of the temporary abnormality timer is equal to or larger than the first detection time (S106). That is, the first detection device 31 determines whether the time during which the second system voltage V2 is smaller than the first threshold continues for the first detection time or longer. More specifically, the first detection device 31 determines whether the voltage drop in the first system 110 or the second system 120 continues for the first detection time or longer.

When it is determined that the value of the temporary abnormality timer is not equal to or larger than the first detection time (S106: No), the first detection device 31 returns to step S103 and repeats the above-described processing.

When it is determined that the value of the temporary abnormality timer is equal to or larger than the first detection time (S106: Yes), the first detection device 31 performs a temporary abnormality determination (S107). The temporary abnormality determination is a determination indicating that the ground fault in the first system 110 or the second system 120 is detected. That is, the first detection device 31 detects the ground fault in the first system 110 or the second system 120.

Next, when the temporary abnormality determination is performed, the first detection device 31 turns off the inter-system connection unit 41 (S108). In addition, when the temporary abnormality determination is performed, the first detection device 31 turns on the battery switch 42 (S109). That is, when the ground fault in the first system 110 or the second system 120 is detected, the first detection device 31 turns off the inter-system connection unit 41 and turns on the battery switch 42.

The processing of step S108 and step S109 may be performed simultaneously.

When the inter-system connection unit 41 is turned off and the battery switch 42 is turned on, electric power is supplied from the first power supply 10 to the first load 101 and the general load 102. In addition, when the inter-system connection unit 41 is turned off and the battery switch 42 is turned on, electric power is supplied from the second power supply 20 to the second load 103.

After the inter-system connection unit 41 is turned off (S108) and the battery switch 42 is turned on (S109), the second detection device 32 determines whether the first system voltage V1 is smaller than the second threshold (S110). That is, the second detection device 32 determines whether the voltage drop of the first system 110 occurs after the inter-system connection unit 41 is turned off.

When it is determined that the first system voltage V1 is smaller than the second threshold (S110: Yes), the second detection device 32 counts up a first abnormality timer (S111). The second detection device 32 includes the first abnormality timer. A value of the first abnormality timer is set to “0” as an initial value. The value of the first abnormality timer indicates a duration time during which the first system voltage V1 is smaller than the second threshold. That is, the second detection device 32 measures the time during which the first system voltage V1 is continuously smaller than the second threshold using the first abnormality timer.

Next, the second detection device 32 clears a first normality timer (S112). The second detection device 32 includes the first normality timer. A value of the first normality timer is set to “0” as an initial value. The value of the first normality timer indicates a duration time during which the first system voltage V1 is equal to or larger than the second threshold. When it is determined that the voltage detected by the first voltage sensor 51 is smaller than the second threshold, the second detection device 32 resets the first normality timer to the initial value.

The order of the processing of step S111 and step S112 may be reversed. In addition, the processing of step S111 and step S112 may be performed simultaneously.

The second detection device 32 determines whether the value of the first abnormality timer is equal to or larger than the second detection time (S113). That is, the second detection device 32 determines whether the time during which the first system voltage V1 is smaller than the second threshold continues for the second detection time or longer. More specifically, after the inter-system connection unit 41 is turned off, the second detection device 32 determines whether the state in which the voltage of the first system 110 is smaller than the second threshold continues for the second detection time or longer.

When it is determined that the value of the first abnormality timer is smaller than the second detection time (S113: No), the second detection device 32 performs the processing of step S120 to be described later.

When it is determined that the value of the first abnormality timer is equal to or larger than the second detection time (S113: Yes), the second detection device 32 sets a first abnormality determination flag to “1” (S114). The second detection device 32 includes the first abnormality determination flag. The first abnormality determination flag is a flag indicating whether the occurrence of a ground fault in the first system 110 is detected. When the first abnormality determination flag is “1”, the first abnormality determination flag indicates that the occurrence of the ground fault in the first system 110 is detected. The first abnormality determination flag is set to “0” as an initial value. When it is determined that the value of the first abnormality timer is equal to or larger than the second detection time, the second detection device 32 detects the occurrence of the ground fault in the first system 110. That is, when it is determined that the value of the first abnormality timer is equal to or larger than the second detection time, the second detection device 32 specifies the first system 110 as an abnormal system.

Next, the second detection device 32 turns on the battery switch 42 (S115). Accordingly, a fail safe control for supplying electric power from the second power supply 20 to the second load 103 is performed, and the FOP is executed by the automatic driving control device 100. When the battery switch 42 is already turned on, step S115 is skipped.

When it is determined that the first system voltage V1 is equal to or larger than the second threshold (S110: No), the second detection device 32 counts up the first normality timer (S116). That is, the second detection device 32 measures the time during which the first system voltage V1 is continuously equal to or larger than the second threshold using the first normality timer.

The second detection device 32 clears the first abnormality timer (S117). That is, when it is determined that the first system voltage V1 is equal to or larger than the second threshold, the second detection device 32 resets the first abnormality timer to the initial value. More specifically, when the first system voltage V1 is equal to or larger than the second threshold within the second detection time after the first system voltage V1 is smaller than the second threshold, the second detection device 32 resets the first abnormality timer to the initial value.

The order of the processing of step S116 and step S117 may be reversed. In addition, the processing of step S116 and step S117 may be performed simultaneously.

Next, the second detection device 32 determines whether the value of the first normality timer is equal to or larger than a third detection time (S118). That is, the second detection device 32 determines whether the time during which the first system voltage V1 is equal to or larger than the second threshold continues for the third detection time or longer.

The third detection time is a preset time. The third detection time is a time for confirming erroneous detection of a ground fault by the first detection device 31. For example, the third detection time is the same as the second detection time.

When it is determined that the value of the first normality timer is smaller than the third detection time (S118: No), the second detection device 32 performs the processing of step S120 to be described later.

When it is determined that the value of the first normality timer is equal to or larger than the third detection time (S118: Yes), the second detection device 32 sets a first normality determination flag to “1” (S119). The second detection device 32 includes the first normality determination flag. The first normality determination flag is a flag indicating whether no ground fault occurs in the first system 110. When the first normality determination flag is “1”, the first normality determination flag indicates that no ground fault occurs in the first system 110. The first normality determination flag is set to “0” as an initial value. When it is determined that the value of the first normality timer is equal to or larger than the third detection time, the second detection device 32 determines that no ground fault occurs in the first system 110. That is, the second detection device 32 confirms that the first system 110 is normal.

The second detection device 32 determines whether the second system voltage V2 is smaller than the second threshold (S120). That is, the second detection device 32 determines whether the voltage drop of the second system 120 occurs after the inter-system connection unit 41 is turned off.

When it is determined that the second system voltage V2 is smaller than the second threshold (S120: Yes), the second detection device 32 counts up a second abnormality timer (S121). The second detection device 32 includes the second abnormality timer. A value of the second abnormality timer is set to “0” as an initial value. The value of the second abnormality timer indicates a duration time during which the second system voltage V2 is smaller than the second threshold. That is, the second detection device 32 measures the time during which the second system voltage V2 is continuously smaller than the second threshold using the second abnormality timer.

Next, the second detection device 32 clears a second normality timer (S122). The second detection device 32 includes the second normality timer. A value of the second normality timer is set to “0” as an initial value. The value of the second normality timer indicates a duration time during which the second system voltage V2 is equal to or larger than the second threshold. When it is determined that the voltage detected by the second voltage sensor 52 is smaller than the second threshold, the second detection device 32 resets the second normality timer to the initial value.

The order of the processing of step S121 and step S122 may be reversed. In addition, the processing of step S121 and step S122 may be performed simultaneously.

Next, the second detection device 32 determines whether the value of the second abnormality timer is equal to or larger than the second detection time (S123). That is, the second detection device 32 determines whether the time during which the second system voltage V2 is smaller than the second threshold continues for the second detection time or longer. More specifically, after the inter-system connection unit 41 is turned off, the second detection device 32 determines whether the state in which the voltage of the second system 120 is smaller than the second threshold continues for the second detection time or longer.

When it is determined that the value of the second abnormality timer is smaller than the second detection time (S123: No), the second detection device 32 performs the processing of step S130 to be described later.

When it is determined that the value of the second abnormality timer is equal to or larger than the second detection time (S123: Yes), the second detection device 32 sets a second abnormality determination flag to “1” (S124). The second detection device 32 includes the second abnormality determination flag. The second abnormality determination flag is a flag indicating whether the occurrence of a ground fault in the second system 120 is detected. When the second abnormality determination flag is “1”, the second abnormality determination flag indicates that the occurrence of the ground fault in the second system 120 is detected. The second abnormality determination flag is set to “0” as an initial value. When it is determined that the value of the second abnormality timer is equal to or larger than the second detection time, the second detection device 32 detects the occurrence of the ground fault in the second system 120. That is, when it is determined that the value of the second abnormality timer is equal to or larger than the second detection time, the second detection device 32 specifies the second system 120 as an abnormal system.

Next, the second detection device 32 turns off the battery switch 42 (S125). Accordingly, no electric power is supplied from the second power supply 20 to the second load 103. Accordingly, a fail safe control for supplying electric power from the first power supply 10 to the first load 101 and the general load 102 is performed, and the FOP is executed by the automatic driving control device 100.

When it is determined that the second system voltage V2 is equal to or larger than the second threshold (S120: No), the second detection device 32 counts up the second normality timer (S126). That is, the second detection device 32 measures the time during which the second system voltage V2 is continuously equal to or larger than the second threshold using the second normality timer.

Next, the second detection device 32 clears the second abnormality timer (S127). That is, when it is determined that the second system voltage V2 is equal to or larger than the second threshold, the second detection device 32 resets the second abnormality timer to the initial value. More specifically, when the second system voltage V2 is equal to or larger than the second threshold within the second detection time after the second system voltage V2 is smaller than the second threshold, the second detection device 32 resets the second abnormality timer to the initial value.

The order of the processing of step S126 and step S127 may be reversed. In addition, the processing of step S126 and step S127 may be performed simultaneously.

Next, the second detection device 32 determines whether the value of the second normality timer is equal to or larger than the third detection time (S128). That is, the second detection device 32 determines whether the time during which the second system voltage V2 is equal to or larger than the second threshold continues for the third detection time or longer.

When it is determined that the value of the second normality timer is smaller than the third detection time (S128: No), the second detection device 32 performs the processing of step S130 to be described later.

When it is determined that the value of the second normality timer is equal to or larger than the third detection time (S128: Yes), the second detection device 32 sets a second normality determination flag to “1” (S129). The second detection device 32 includes the second normality determination flag. The second normality determination flag is a flag indicating whether no ground fault occurs in the second system 120. When the second normality determination flag is “1”, the second normality determination flag indicates that no ground fault occurs in the second system 120. The second normality determination flag is set to “0” as an initial value. When it is determined that the value of the second normality timer is equal to or larger than the third detection time, the second detection device 32 determines that no ground fault occurs in the second system 120. That is, the second detection device 32 confirms that the second system 120 is normal.

The processing from step S120 to step S129 and the processing from step S110 to step S119 may be reversed.

The second detection device 32 determines whether one of the first abnormality determination flag and the first normality determination flag of the first system 110 is confirmed to be “1”, and whether one of the second abnormality determination flag and the second normality determination flag of the second system 120 is confirmed to be “1” (S130). That is, the second detection device 32 determines whether the first system 110 is confirmed to be normal or abnormal, and determines whether the second system 120 is confirmed to be normal or abnormal. When it is not confirmed whether both the systems are normal or abnormal (S130: No), the second detection device 32 returns to step S110 and repeats the above-described processing. In other words, the processing from step S110 to step S130 is repeated until the first system 110 and the second system 120 are confirmed to be normal or abnormal.

When the first system 110 and the second system 120 are confirmed to be normal or abnormal (S130: Yes), that is, when either the first abnormality determination flag or the first normality determination flag is “1” and either the second abnormality determination flag or the second normality determination flag is “1”, the second detection device 32 determines whether the normality determination flags of both systems are set to “1” (S131). More specifically, the second detection device 32 determines whether the normality determination flags of both the first system 110 and the second system 120 are set to “1”. In other words, the second detection device 32 determines whether no ground fault occurs in the systems 110 and 120, and the systems 110 and 120 are confirmed to be normal.

When each of the normality determination flags is set to “1” (S131: Yes), that is, when no ground fault occurs in the first system 110 and the second system 120 and the first system 110 and the second system 120 are confirmed to be normal, the second detection device 32 determines that the voltage drop detected by the first detection device 31 is caused by a temporary overload, and turns on the inter-system connection unit 41 (S132). In addition, the second detection device 32 turns off the battery switch 42 (S133).

Accordingly, the first system 110 and the second system 120 are electrically connected to each other to return to a normal state, and the electric power is supplied from the first power supply 10 to the first load 101, the general load 102, and the second load 103.

The order of the processing of step S132 and step S133 may be reversed. In addition, the processing of step S132 and step S133 may be performed simultaneously.

When at least one of the normality determination flags is not set to “1” (S131: No), the second detection device 32 ends the current processing. That is, the determination of “No” in step S131 indicates that the first abnormality determination flag or the second abnormality determination flag is set to “1”. The second detection device 32 maintains a current state of the inter-system connection unit 41 and a current state of the battery switch 42. Accordingly, the switch drive device 3 performs the fail safe control for a normal system while blocking the inter-system connection unit 41.

When the first detection device 31 determines that a ground fault occurs in the first system 110 or the second system 120, the inter-system connection unit 41 is turned off, and the electrical connection between the first system 110 and the second system 120 is disconnected. The electric power is supplied from the first power supply 10 to the first load 101 and the general load 102. In addition, the electric power is supplied from the second power supply 20 to the second load 103. Accordingly, the second detection device 32 makes a final determination as to which system a ground fault occurs. Therefore, electric power is consumed for the final determination from the second power supply 20, which is the backup power supply, and the power storage amount decreases.

When the second detection device 32 determines that no ground fault occurs in the first system 110 and the second system 120, that is, when the ground fault detected by the first detection device 31 is erroneously detected, the inter-system connection unit 41 is turned on, and automatic driving is enabled.

However, when the power storage amount of the second power supply 20 is smaller than the first predetermined power storage amount, which is a permission threshold for automatic driving, the automatic driving is prohibited. For example, when the erroneous detection of the ground fault by the first detection device 31 is repeated, the power storage amount of the second power supply 20 may decrease, and the power storage amount of the second power supply 20 may be smaller than the first predetermined power storage amount.

In this case, even if the second detection device 32 determines that no ground fault occurs in the first system 110 and the second system 120 and the inter-system connection unit 41 is turned on, the automatic driving is prohibited. In this way, when the erroneous detection of the ground fault by the first detection device 31 occurs, a function of the load is limited.

The power supply control device 1 according to the embodiment includes the inter-system connection unit 41, the first detection device 31, and the second detection device 32. The inter-system connection unit 41 can disconnect the electrical connection between the first system 110 that supplies the electric power of the first power supply 10 to the first load 101 and the second system 120 that supplies the electric power of the second power supply 20 to the second load 103. When a state in which a voltage indicating the state of the first system 110 or the state of the second system 120 exceeds the first threshold for abnormality determination from the normal value side continues for the first detection time, the first detection device 31 detects an abnormality of the first system 110 or an abnormality of the second system 120, and blocks the inter-system connection unit 41. The second detection device 32 specifies in the first system 110 and the second system 120, as an abnormal system, a system in which a state in which the voltage exceeds the second threshold for abnormality determination from the normal value side continues for the second detection time shorter than the first detection time, after the first detection device 31 detects an abnormality.

Accordingly, the power supply control device 1 can reduce the erroneous detection of the ground fault by the first detection device 31. For example, when the voltage detected by the second voltage sensor 52 temporarily drops due to a voltage fluctuation instead of a ground fault, the power supply control device 1 returns the voltage to an original state within the long first detection time. Accordingly, the first detection device 31 does not detect the ground fault, and the erroneous detection of the ground fault can be reduced. Therefore, the power supply control device 1 can prevent the electric power from being supplied from the second power supply 20 to the second load 103, and can prevent a decrease in the power storage amount of the second power supply 20. The power supply control device 1 can prevent the automatic driving from being prohibited until the second power supply 20 is charged after the power storage amount of the second power supply 20 decreases. That is, the power supply control device 1 can prevent functions of the first load 101 and the second load 103 from being limited. The power supply control device 1 can increase chances of executing automatic driving.

The first detection device 31 and the second detection device 32 are implemented by the microcomputer.

Accordingly, the power supply control device 1 can improve a degree of freedom of setting for ground fault detection conditions of the detection devices 31 and 32.

The first detection device 31 and the second detection device 32 may be implemented by separate microcomputers. Specifically, the first detection device 31 is implemented by one microcomputer, and the second detection device 32 is implemented by another microcomputer. In this case, when the first detection device 31 detects a ground fault, the occurrence of the ground fault is notified to the second detection device 32. The second detection device 32 receives the notification and makes a final determination.

### Second Embodiment

Next, the power supply control device 1 according to a second embodiment will be described. Hereinafter, portions different from that of the first embodiment will be described. The description of the same configuration and the same processing as those of the first embodiment will be omitted.

In the first embodiment, the first detection device 31 detects the ground fault only after a state in which the second system voltage V2 drops to the first threshold or less continues for the first detection time or longer. Therefore, when a true ground fault occurs in the first system 110 or the second system 120, the detection of the ground fault may be delayed. In the second embodiment, it is possible to quickly detect the occurrence of a true ground fault while reducing erroneous detection due to a temporary voltage drop.

When the second system voltage V2 is smaller than a third threshold, the first detection device 31 according to the second embodiment detects a ground fault in the first system 110 or a ground fault in the second system 120. The third threshold is a preset value. The third threshold is smaller than the first threshold. That is, a difference between the third threshold and a normal value of the voltage is larger than a difference between the first threshold and the normal value of the voltage.

When the second system voltage V2 is smaller than the third threshold, the first detection device 31 detects the ground fault in the first system 110 or the ground fault in the second system 120 without waiting for the elapse of the first detection time.

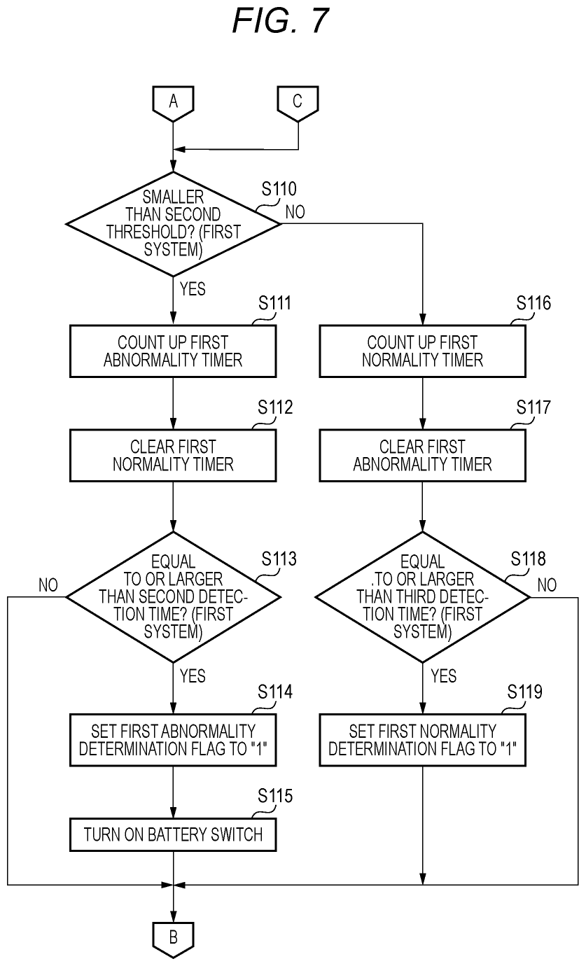

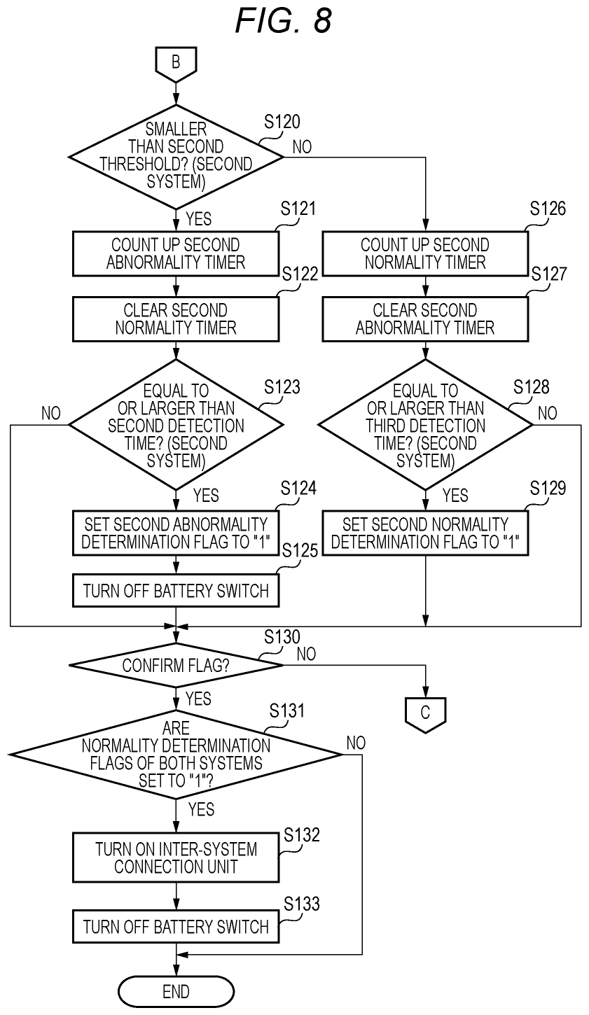

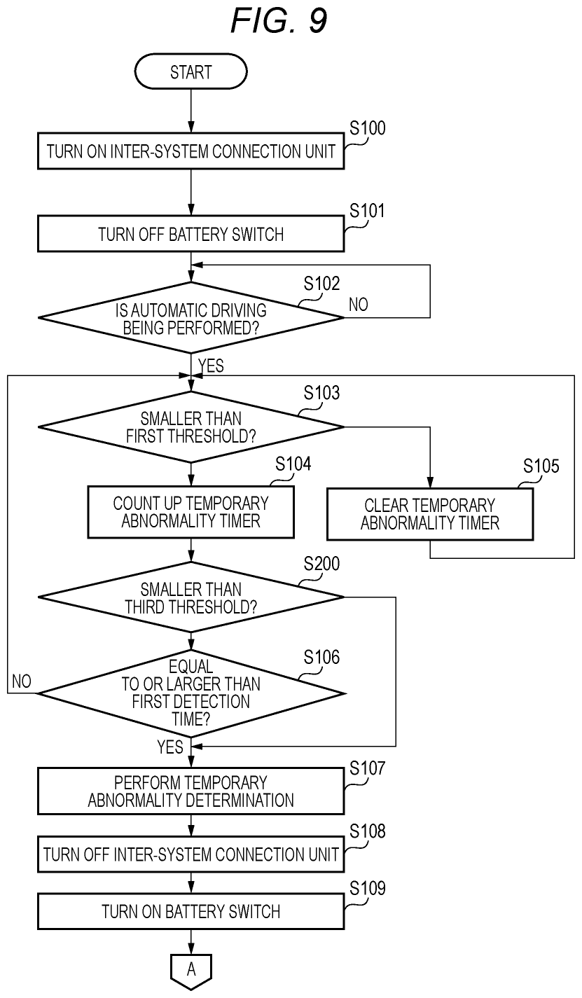

Next, an abnormality occurrence processing according to the second embodiment will be described with reference to FIGS. 9, 7, and 8. FIG. 9 is a flowchart illustrating the abnormality occurrence processing according to the second embodiment. In the abnormality occurrence processing according to the first embodiment, the processing illustrated in FIGS. 7 and 8 is the same as the abnormality occurrence processing according to the second embodiment.

The processing from steps S100 to S105 in FIG. 9 is the same as the processing from steps S100 to S105 in FIG. 6.

After the processing of step S104, the first detection device 31 determines whether the second system voltage V2 is smaller than the third threshold (S200).

When it is determined that the second system voltage V2 is smaller than the third threshold (S200: Yes), the first detection device 31 performs a temporary abnormality determination without waiting for the elapse of the first detection time (S107).

When the second system voltage V2 is equal to or larger than the third threshold (step S200: No), the first detection device 31 determines whether the value of the temporary abnormality timer is equal to or larger than the first detection time (S106). When the second system voltage V2 is smaller than the first threshold and is equal to or larger than the third threshold, the first detection device 31 determines whether the value of the temporary abnormality timer is equal to or larger than the first detection time.

The order of the processing of step S104 and step S200 may be reversed.

The processing from steps S106 to S109 in FIG. 9 is the same as the processing from steps S106 to S109 in FIG. 6.

When the state in which the second system voltage V2 is smaller than the first threshold continues for the first detection time or longer, the first detection device 31 detects the ground fault in the first system 110 or the ground fault in the second system 120. On the other hand, when the second system voltage V2 is smaller than the third threshold, the first detection device 31 detects the ground fault in the first system 110 or the ground fault in the second system 120 without waiting for the elapse of the first detection time. The difference between the third threshold and the normal value of the voltage is larger than the difference between the first threshold and the normal value of the voltage. That is, the third threshold is smaller than the first threshold.

Accordingly, when a ground fault occurs and the dropping of the second system voltage V2 is large, that is, when there is a high possibility that a true ground fault occurs, the first detection device 31 can quickly turn off the inter-system connection unit 41, can quickly end the specification of the ground fault in the second detection device 32, and can prevent electric power loss of the first power supply 10 or the second power supply 20 due to the ground fault. Therefore, the FOP is executed early, and a vehicle can early and reliably perform evacuation travel to a safe place. Therefore, the power supply control device 1 can improve safety.

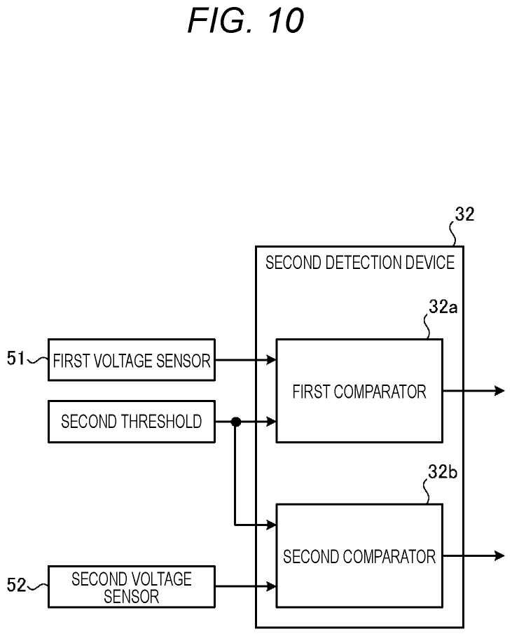

The second detection device 32 may be implemented by a hardware circuit. For example, as illustrated in FIG. 10, the second detection device 32 includes a first comparator 32a and a second comparator 32b. The first comparator 32a is a comparator that compares the first system voltage V1 with the second threshold. The second comparator 32b is a comparator that compares the second system voltage V2 with the second threshold. FIG. 10 is a diagram illustrating the second detection device 32 according to a modification.

Since the second detection device 32 is implemented by the hardware circuit, the second detection device 32 can quickly detect the occurrence of the ground fault and specify the occurrence of the ground fault. Therefore, when the ground fault occurs, the FOP is executed early. The FOP is executed early, and thus the vehicle can early perform evacuation travel to the safe place. Therefore, the power supply control device 1 can improve safety. The second detection time for ground fault detection of the second detection device 32 in this case is a time until the comparators 32a and 32b are inverted from a normal side to an abnormal side when the voltage sensors 51 and 52 drop below the second threshold, and is substantially 0.

In the above-described embodiment, the example in which the first threshold and the second threshold have the same value has been described, but the present invention is not limited thereto. The first threshold and the second threshold may be different values.

The first threshold and the second threshold may be set such that the first threshold has a higher sensitivity for detecting an abnormality than the second threshold. In this case, a difference between the first threshold and the normal value of the physical quantity is smaller than a difference between the second threshold and the normal value of the physical quantity. When the physical quantity is a voltage, the first threshold is larger than the second threshold.

Accordingly, the first detection device 31 can early detect the ground fault in the first system 110 or the ground fault in the second system 120, and the second detection device 32 can specify a ground fault point more reliably. Therefore, the FOP is executed early, and the vehicle can early perform evacuation travel to the safe place. Therefore, the power supply control device 1 can improve safety.

The first threshold and the second threshold may be set such that the first threshold has a lower sensitivity for detecting an abnormality than the second threshold. In this case, the difference between the first threshold and the normal value of the physical quantity is larger than the difference between the second threshold and the normal value of the physical quantity. When the physical quantity is the voltage, the first threshold is smaller than the second threshold.

Accordingly, the first detection device 31 can reduce erroneous detection of the ground fault when the voltage drops due to a voltage fluctuation or the like in a state in which no ground fault actually occurs. Therefore, the power supply control device 1 can prevent the electric power from being supplied from the second power supply 20 to the second load 103 due to the erroneous detection of the ground fault, and can prevent a decrease in the power storage amount of the second power supply 20. Therefore, the power supply control device 1 can prevent the automatic driving from being inhibited due to the decrease in the power storage amount of the second power supply 20. That is, the power supply control device 1 can increase chances of executing automatic driving.

In the above-described embodiment, the example in which the physical quantity is the voltage has been described, but the present invention is not limited thereto. The physical quantity may be a current. When the physical quantity is the current, the first threshold and the second threshold are larger than a current of a normal value. In addition, when the physical quantity is the current, the third threshold is larger than the first threshold.

As an appendix, the features of the present invention are shown below. (1)

A power supply control device including:
an inter-system connection unit configured to disconnect electrical connection between a first system that supplies electric power of a first power supply to a first load and a second system that supplies electric power of a second power supply to a second load;
a first detection device configured to detect an abnormality of the first system or an abnormality of the second system when a state in which a physical quantity indicating a state of the first system or a state of the second system exceeds a first threshold for abnormality determination from a normal value side continues for a first detection time, and block the inter-system connection unit; and
a second detection device configured to specify in the first system and the second system, as an abnormal system, a system in which a state in which the physical quantity exceeds a second threshold for abnormality determination from the normal value side continues for a second detection time shorter than the first detection time, after the first detection device detects an abnormality. (2)

The power supply control device according to (1), in which
the first detection device is implemented by a microcomputer, and
the second detection device is implemented by a hardware circuit. (3)

The power supply control device according to (1), in which the first detection device and the second detection device are implemented by a microcomputer. (4)

The power supply control device according to any one of (1) to (3), in which a difference between the first threshold and a normal value of the physical quantity is smaller than a difference between the second threshold and the normal value of the physical quantity. (5)

The power supply control device according to any one of (1) to (3), in which a difference between the first threshold and a normal value of the physical quantity is larger than a difference between the second threshold and the normal value of the physical quantity. (6)

The power supply control device according to any one of (1) to (5), in which
the first detection device is configured to detect the abnormality of the first system or the abnormality of the second system without waiting for elapse of the first detection time when the physical quantity exceeds a third threshold from the normal value side before the state in which the physical quantity exceeds the first threshold from the normal value side continues for the first detection time or longer, and
a difference between the third threshold and a normal value of the physical quantity is larger than a difference between the first threshold and the normal value of the physical quantity. (7)

A method for controlling a power supply control device, including:
detecting an abnormality of a first system configured to supply electric power of a first power supply to a first load or an abnormality of a second system configured to supply electric power of a second power supply to a second load when a state in which a physical quantity indicating a state of the first system or a state of the second system exceeds a first threshold for abnormality determination from a normal value side continues for a first detection time to block an inter-system connection unit configured to disconnect electrical connection between the first system and the second system; and
specifying in the first system and the second system, as an abnormal system, a system in which a state in which the physical quantity exceeds a second threshold for abnormality determination from the normal value side continues for a second detection time shorter than the first detection time, after the abnormality of the first system and the abnormality of the second system are detected.

Further effects and modifications can be easily derived by those skilled in the art. Therefore, broader aspects of the present invention are not limited to the specific details and representative embodiments shown and described above. Therefore, various modifications can be made without departing from the spirit or scope of the general inventive concept as defined by the appended claims and equivalents thereof.

What is claimed is:

1. A power supply control device comprising:
an inter-system connection unit configured to disconnect electrical connection between a first system that supplies electric power of a first power supply to a first load and a second system that supplies electric power of a second power supply to a second load;
a first detection device configured to detect an abnormality of the first system or an abnormality of the second system when a state in which a physical quantity indicating a state of the first system or a state of the second system exceeds a first threshold for abnormality determination from a normal value side continues for a first detection time, and block the inter-system connection unit; and
a second detection device configured to specify in the first system and the second system, as an abnormal system, a system in which a state in which the physical quantity exceeds a second threshold for abnormality determination from the normal value side continues for a second detection time shorter than the first detection time, after the first detection device detects an abnormality.

2. The power supply control device according to claim 1, wherein
the first detection device is implemented by a microcomputer, and
the second detection device is implemented by a hardware circuit.

3. The power supply control device according to claim 1, wherein
the first detection device and the second detection device are implemented by a microcomputer.

4. The power supply control device according to claim 1, wherein
a difference between the first threshold and a normal value of the physical quantity is smaller than a difference between the second threshold and the normal value of the physical quantity.

5. The power supply control device according to claim 1, wherein
a difference between the first threshold and a normal value of the physical quantity is larger than a difference between the second threshold and the normal value of the physical quantity.

6. The power supply control device according to claim 1, wherein
the first detection device is configured to detect the abnormality of the first system or the abnormality of the second system without waiting for elapse of the first detection time when the physical quantity exceeds a third threshold from the normal value side before the state in which the physical quantity exceeds the first threshold from the normal value side continues for the first detection time or longer, and
a difference between the third threshold and a normal value of the physical quantity is larger than a difference between the first threshold and the normal value of the physical quantity.

7. A method for controlling a power supply control device, comprising:
detecting an abnormality of a first system configured to supply electric power of a first power supply to a first load or an abnormality of a second system configured to supply electric power of a second power supply to a second load when a state in which a physical quantity indicating a state of the first system or a state of the second system exceeds a first threshold for abnormality determination from a normal value side continues for a first detection time to block an inter-system connection unit configured to disconnect electrical connection between the first system and the second system; and
specifying in the first system and the second system, as an abnormal system, a system in which a state in which the physical quantity exceeds a second threshold for abnormality determination from the normal value side continues for a second detection time shorter than the first detection time, after the abnormality of the first system and the abnormality of the second system are detected.
